(19) United States
(12) Patent Application Publication
(10) Pub. No.: US 2025/0087272 A1
(43) Pub. Date: Mar. 13, 2025

(54) METHOD FOR OPERATING FERROELECTRIC-BASED THREE-DIMENSIONAL FLASH MEMORY INCLUDING DATA STORAGE PATTERN

(71) Applicant: Samsung Electronics Co., Ltd., Suwon-si, Gyeonggi-do (KR)

(72) Inventors: Yun Heub Song, Seoul (KR); Sun Jun Choi, Seoul (KR); Jea Min Shim, Seoul (KR)

(21) Appl. No.: 18/725,991

(22) PCT Filed: Jan. 20, 2023
(86) PCT No.: PCT/KR2023/000998

§ 371 Date: Jul. 1, 2024

(30) Foreign Application Priority Data
Nov. 2, 2022 (KR) 10-2022-0017915

(51) Int. Cl. G11C 16/10; G11C 16/04; G11C 16/08

(52) U.S. Cl. CPC G11C 16/102; G11C 16/0483; G11C 16/08

(57) ABSTRACT

Disclosed is a method for operating ferroelectric-based three-dimensional flash memory including a data storage pattern. According to one embodiment, a program operation method of three-dimensional flash memory may comprise the steps of: adjusting the value of a program voltage to be applied to a selected word line corresponding to a target memory cell that is the target of a program operation among word lines on the basis of the slope at which a voltage pulse increases in an incremental step pulse programming (ISPP) method; applying the adjusted value of the program voltage to the selected word line; applying a pass voltage to each of the non-selected word lines excluding the selected word line among the word lines; and performing a program operation on the target memory cell in response to the adjusted value of the program voltage being applied to the selected word line and the pass voltage being applied to each of the non-selected word lines.

### TECHNICAL FIELD

The following embodiments relate to an operation method of a three-dimensional flash memory, and more particularly, to an operation method of a three-dimensional flash memory including a ferroelectric-based data storage pattern.

### BACKGROUND ART

A flash memory device is an electrically erasable programmable read only memory (EEPROM) that controls input and output of data electrically by Fowler-Nordheim ((F-N) tunneling or hot electron injection and is commonly used in computers, digital computers, MP3 players, game systems, memory sticks, and so on.

These flash memory devices are required to have an increased degree of integration to satisfy the excellent performance and low price demanded by consumers, and a three-dimensional structure in which memory cell transistors are arranged vertically to form a memory cell string (CSTR) is proposed.

In accordance with recent trends to reduce a cross-sectional area of a memory cell string (CSTR) for integration of a three-dimensional flash memory, a technology is proposed in which a single layer of a ferroelectric material is used instead of a blocking oxide-nitride-tunnel oxide (ONO) used as a data storage pattern (DSP).

However, research and development of a method of operating a three-dimensional flash memory in which a ferroelectric-based DSP is used have been insufficient.

Accordingly, in the following embodiments, a method of operating a three-dimensional flash memory including a ferroelectric-based DSP is proposed.

### DISCLOSURE

### Technical Problem

Embodiments propose a program operation method of a three-dimensional flash memory for adjusting a program voltage by applying an incremental step pulse programming (ISPP) method to present a method for a program operation using a ferroelectric-based data storage pattern.

Embodiments propose a program operation method of a three-dimensional flash memory for multi-leveling by adjusting a value of a program voltage to a plurality of values based on a slope.

In this case, embodiments propose a program operation method of a three-dimensional flash memory for adjusting a value of a pass voltage to achieve the stability of a program state.

However, the technical objectives to be achieved by the present disclosure are not limited thereto, and may be variously extended without departing from the spirit and scope of the present disclosure.

### Technical Solution

According to an embodiment, a program operation method of a three-dimensional flash memory including word lines apart from each other and stacked in a vertical direction while extending in a horizontal direction on a substrate, and vertical channel structures formed to pass through the word lines and extending in the vertical direction, each of the vertical channel structures including a vertical channel pattern extending in the vertical direction and a ferroelectric-based data storage pattern formed to cover an outer wall of the vertical channel pattern, and the data storage pattern and the vertical channel pattern constituting memory cells corresponding to the word lines includes adjusting a value of a program voltage to be applied to a selected word line corresponding to a target memory cell as a target of the program operation from among the word lines by applying an incremental step pulse programming (ISPP) method, applying the adjusted value of the program voltage to the selected word line, applying a pass voltage to each of unselected word lines except for the selected word line from among the word lines, and performing the program operation on the target memory cell in response to the adjusted value of the program voltage being applied to the selected word line and the pass voltage being applied to the unselected word lines.

According to an aspect, the adjusting of the value of the program voltage may include adjusting the value of the program voltage to be applied to the selected word line corresponding to the target memory cell as the target of the program operation from among the word lines, based on a slope in which a voltage pulse increases in the ISPP method.

According to another aspect, the adjusting of the value of the program voltage may include multi-leveling the three-dimensional flash memory by adjusting the voltage of the program voltage to a plurality of values.

According to another aspect, when a vertical channel pattern of a selected vertical channel structure including the target memory cell is of an N type, the adjusting of the value of the program voltage may include adjusting the value of the program voltage to a positive value, and the applying of the pass voltage may include applying a pass voltage of a positive value.

According to another aspect, when a vertical channel pattern of a selected vertical channel structure including the target memory cell is of a P type, the adjusting of the value of the program voltage may include adjusting the value of the program voltage to a negative value, and the applying of the pass voltage may include applying a pass voltage of a negative value.

According to another aspect, the applying of the pass voltage may include adjusting a value of the pass voltage based on stability of a program state that the target memory cell has due to the program operation.

### Advantageous Effects

Embodiments propose a method for a program operation using a ferroelectric-based data storage pattern by proposing a program operation method of a three-dimensional flash memory for adjusting a program voltage by applying an incremental step pulse programming (ISPP) method.

Embodiments propose a program operation method of a three-dimensional flash memory for multi-leveling by adjusting a value of a program voltage to a plurality of values based on a slope.

In this case, embodiments propose a program operation method of a three-dimensional flash memory for adjusting a value of a pass voltage to achieve the stability of a program state.

However, the effects of the present disclosure are not limited to the above effects, and may be variously extended without departing from the spirit and scope of the present disclosure.

### DESCRIPTION OF DRAWINGS

FIG. 1 is a schematic circuit diagram illustrating an array of three-dimensional flash memory according to an embodiment.

FIG. 2 is a plan view illustrating a structure of a three-dimensional flash memory according to an embodiment.

FIG. 3 is a cross-sectional view illustrating a structure of a three-dimensional flash memory according to an embodiment and corresponds to a cross section of the three-dimensional flash memory taken along a line A-A of FIG. 2.

FIG. 4 is a flowchart illustrating a program operation method of a three-dimensional flash memory according to an embodiment.

FIGS. 5A to 6B are diagrams for describing adjusting a value of a program voltage in the program operation method illustrated in FIG. 4.

FIG. 7 is a flowchart illustrating an erase operation method of a three-dimensional flash memory, according to an embodiment.

FIG. 8 is a flowchart illustrating a read operation method of a three-dimensional flash memory, according to an embodiment.

### BEST MODE

Hereinafter, embodiments of the present disclosure will be described in detail with reference to the accompanying drawings. However, the present disclosure is not limited by the embodiments. Like reference numerals in the drawings denote like elements.

In the specification, the terminologies used herein are used to properly express embodiment of the present disclosure, which may vary depending on the intent of a viewer or an operator, or customs in the art to which the present disclosure belongs. Therefore, the definitions of the terminologies need to be made based on the contents throughout the specification. For example, in this specification, the singular forms include plural forms unless specifically stated. The terms “comprises” and/or “comprising” when used in the specification specify the presence of stated components, stages, operations, and/or devices, but do not preclude the presence or addition of one or more other components, stages, operations, and/or devices. Although the terms first, second, etc. may be used herein to describe various regions, directions, shapes, etc., these regions, directions, and shapes should not be limited by these terms. These terms are only used to distinguish a certain region, direction, or shape from another region, direction, or shape. Thus, in an embodiment, a portion referred to as a first portion may be referred to as a second portion in another embodiment.

It should also be understood that the various embodiments of the present disclosure are different, but not necessarily mutually exclusive. For example, certain shapes, structures, and characteristics described herein may be implemented in other embodiments without departing from the spirit and scope of the present disclosure in connection with one embodiment. It should also be understood that the position, arrangement, or configuration of individual components in the scope of each embodiment may be changed without departing from the spirit and scope of the present disclosure.

Hereinafter, a method of operating a three-dimensional flash memory including a ferroelectric-based data storage pattern (DSP) will be described in detail with reference to the accompanying drawings.

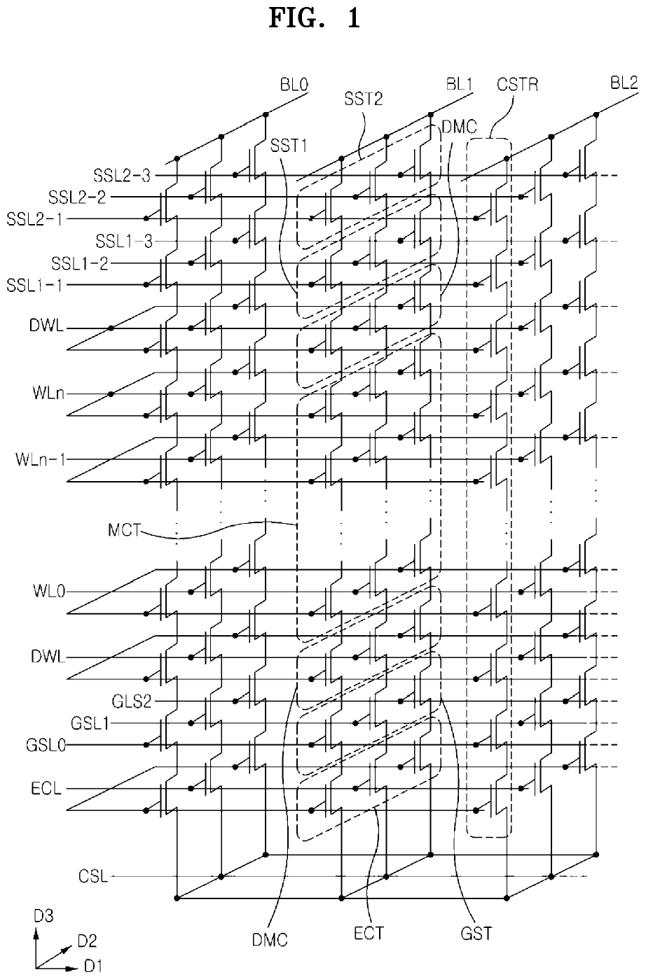

FIG. 1 is a schematic circuit diagram illustrating an array of three-dimensional flash memory according to an embodiment.

Referring to FIG. 1, the array of the three-dimensional flash memory according to an embodiment may include a common source line CSL, a plurality of bit lines BL0, BL1, and BL2, and a plurality of cell strings CSTR located between the common source line CSL and the bit lines BL0, BL1, and BL2.

The bit lines BL0, BL1, and BL2 may be arranged apart from each other in a first direction D1 and may be two-dimensionally arranged while extend in a second direction D2. The first direction D1, the second direction D2, and the third direction D3 are orthogonal to each other and may form the Cartesian coordinate system defined by X, Y, and Z axes.

The plurality of cell strings CSTR may be connected in parallel to each other in each of the bit lines BL0, BL1, and BL2. The cell strings CSTR may be commonly connected to the common source line CSL while being provided between the bit lines BL0, BL1, and BL2 and the one common source line CSL. In this case, the common source line CSL may be provided in a plural number and the plurality of common source lines CSL may be apart from each other in the second direction D2 and two-dimensionally arranged while extending in the first direction D1. Electrically the same voltage may be applied to the plurality of common source lines CSL, but the present disclosure is not limited thereto, and the plurality of common source lines CSL may be electrically and independently controlled, and thus different voltages may be applied to the plurality of common source lines CSL.

The cell strings CSTR may be apart from each other in the second direction D2 in each bit line while extending in the third direction D3. According to an embodiment, each of the cell strings CSTR may include a ground selection transistor GST connected to the common source line CSL, first and second string selection transistors SST1 and SST2 connected to the bit lines BL0, BL1, and BL2 and connected in series to each other, memory cell transistors MCT arranged between the ground selection transistor GST and the first and second string selection transistors SST1 and SST2 and connected in series to each other, and an erasable control transistor ECT. Each of the memory cell transistors MCT may include a data storage element.

For example, each of the cell strings CSTR may include first and second string selection transistors SST1 and SST2 connected in in series to each other, and the second string selection transistor SST2 may be connected to one of the bit lines BL0, BL1, and BL2. However, the present disclosure is not limited thereto, and each of the cell strings CSTR may include one string selection transistor. As another example, in each of the cell strings CSTR, the ground selection transistor GST may include a plurality of MOS transistors connected in series to each other, similarly to the first and second string selection transistors SST1 and SST2.

One cell string CSTR may include the plurality of memory cell transistors MCT having different distances from the common source lines CSL. That is, the memory cell transistors MCT may be connected in series to each other while being arranged between the first string selection transistor SST1 and the ground selection transistor GST in the third direction D3. The erasable control transistor ECT may be connected between the ground selection transistor GST and the common source lines CSL. Each of the cell strings CSTR may further include dummy cell transistors DMC connected between the first string selection transistor SST1 and the uppermost transistor of the memory cell transistors MCT and connected between the ground selection transistor GST and the lowermost transistor of the memory cell transistors MCT.

According to an embodiment, the first string selection transistor SST1 may be controlled by first string selection lines SSL1-1, SSL1-2, and SSL1-3, and the second string selection transistor SST2 may be controlled by second string selection lines SSL2-1, SSL2-2, and SSL2-3. The memory cell transistors MCT may be controlled by a plurality of word lines WL0 to WLn, respectively, and the dummy cell transistors DMC may be controlled by dummy word lines DWL. The ground selection transistor GST may be controlled by ground selection lines GSL0, GSL1, and GSL2, and the erasable control transistor ECT may be controlled by an erasable control line ECL. The erasable control transistor ECT may be provided in a plural number. The common source lines CSL may be commonly connected to sources of the erasable control transistors ECT.

Gate electrodes of the memory cell transistors MCT, which are provided at substantially the same distance from the common source lines CSL, may be commonly connected to one of the word lines WL0 to WLn, DWL to be in an equipotential state. However, the present disclosure is not limited thereto, and even if the gate electrodes of the memory cell transistors MCT are provided at substantially the same level from the common source lines CSL, the gate electrodes provided in different rows or columns may be independently controlled.

The ground selection lines GSL0, GSL1, and GSL2, the first string selection lines SSL1-1, SSL1-2, and SSL1-3, the first string selection lines SSL1-1, SSL1-2, and SSL1-3, and the second string selection lines SSL2-1, SSL2-2, and SSL2-3 may extend in the first direction D1, may be apart from each other in the second direction D2, and may be two-dimensionally arranged. The ground selection lines GSL0, GSL1, and GSL2, the first string selection lines SSL1-1, SSL1-2, and SSL1-3, and the second string selection lines SSL2-1, SSL2-2, and SSL2-3, which are provided at substantially the same level from the common source lines CSL, may be electrically separated from each other. The erasable control transistors ECT of different cell strings CSTR may be controlled by the common erasable control line ECL. The erasable control transistors ECT may generate gate induced drain leakage (hereinafter, GIDL) during an erase operation of a memory cell array. In some embodiments, an erase voltage may be applied to the bit lines BL0, BL1, and BL2 and/or the common source lines CSL during an erase operation of the memory cell array, and a gate induced leakage current may be generated in a string selection transistor SST and/or the erasable control transistors ECT.

The aforementioned string selection line SSL may also be referred to as an upper selection line USL, and the ground selection line GSL may be referred to as a lower selection line.

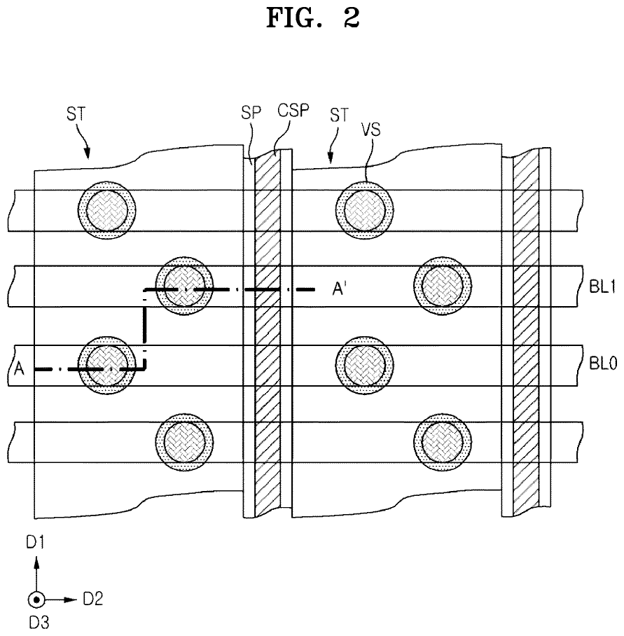

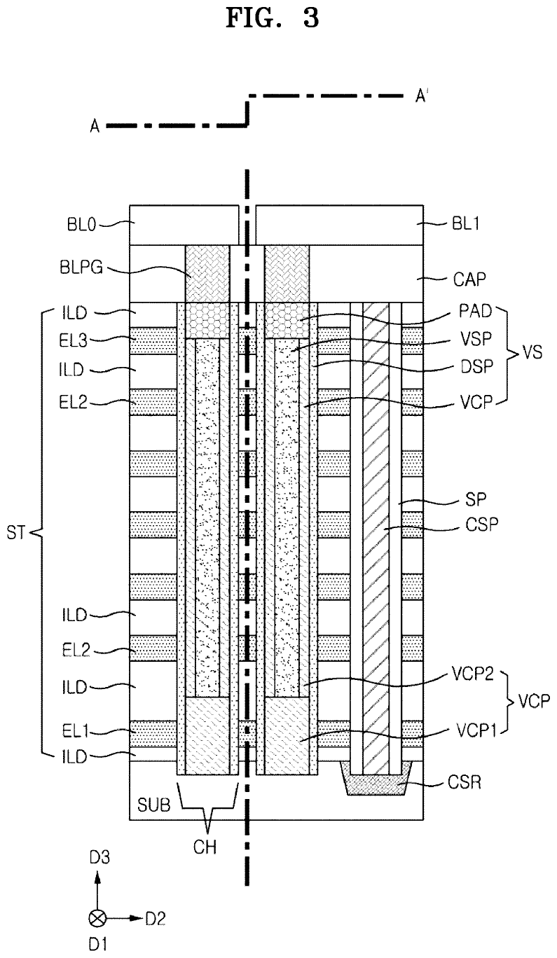

FIG. 2 is a plan view illustrating a structure of a three-dimensional flash memory according to an embodiment, and FIG. 3 is a cross-sectional view illustrating a structure of a three-dimensional flash memory according to an embodiment and corresponds to a cross section of the three-dimensional flash memory taken along a line A-A′ of FIG. 2.

Referring to FIGS. 2 and 3, a substrate SUB may be a semiconductor substrate such as a silicon substrate, a silicon-germanium substrate, a germanium substrate, or a monocrystalline epitaxial layer grown on a monocrystalline silicon substrate. The substrate SUB may be doped with a first conductive impurity (e.g., a P-type impurity).

Stack structures ST may be disposed on the substrate SUB. The stack structures ST may be two-dimensionally arranged in the second direction D2 while extending in the first direction D1. The stack structures ST may be apart from each other in the second direction D2.

Each of the stack structures ST may include gate electrodes EL1, EL2, and EL3 and interlayer insulating layers ILD, which are alternately stacked in a vertical direction (e.g., the third direction D3) perpendicular to an upper surface of the substrate SUB. The stack structures ST may have a substantially flat upper surface. That is, the upper surface of the stack structures ST may be parallel to an upper surface of the substrate SUB. Hereinafter, the vertical direction refers to the third direction D3 or a reverse direction of the third direction D3.

Referring back to FIG. 1, each of the gate electrodes EL1, EL2, and EL3 may be one of the erasable control line ECL, the ground selection lines GSL0, GSL1, and GSL2, the word lines WL0 to WLn, DWL, the first string selection lines SSL1-1, SSL1-2, and SSL1-3, and the second string selection lines SSL2-1, SSL2-2, and SSL2-3, which are sequentially stacked on the substrate SUB.

Each of the gate electrodes EL1, EL2, and EL3 may have substantially the same thickness in the third direction D3 while extending in the first direction D1. Hereinafter, the thickness refers to a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., doped silicon), a metal (e.g., tungsten (W), copper (Cu), aluminum (Al), titanium (Ti), tantalum (Ta), molybdenum (Mo), ruthenium (Ru), and gold (Au)), or a conductive metal nitride (e.g., titanium nitride, and tantalum nitride). Each of the gate electrodes EL1, EL2, and EL3 may include at least one of all metal materials to be formed via ALD in addition to the metal material described above.

In more detail, the gate electrodes EL1, EL2, and EL3 may include the lowermost first gate electrode EL1, the uppermost third gate electrode EL3, and the plurality of second gate electrodes EL2 between the first gate electrode EL1 and the third gate electrode EL3. Although the first gate electrode EL1 and the third gate electrode EL3 are each illustrated as singular numbers, but this is illustrative and not limited thereto, and the first gate electrode EL1 and the third gate electrode EL3 may be provided in a plural number as necessary. The first gate electrode EL1 may correspond to any one of the ground selection lines GSL0, GSL1, and GSL2 illustrated in FIG. 1. The second electrode EL2 may correspond to any one of the word lines WL0 to WLn, DWL illustrated in FIG. 1. The third gate electrode EL3 may correspond to any one of the first string selection lines SSL1-1, SSL1-2, and SSL1-3 of FIG. 1 or any one of the second string selection lines SSL2-1, SSL2-2, and SSL2-3 of FIG. 1.

Although not shown, an end of each of the stack structures ST may have a stepwise structure in the first direction D1. In more detail, the gate electrodes EL1, EL2, and EL3 of the stack structures ST may have a length in the first direction D1, which decreases away from the substrate SUB. The length of the third gate electrode EL3 in the first direction D1 may be the smallest, and a distance between the third gate electrode EL3 and the substrate SUB in the third direction D3 may be the largest. The length of the first gate electrode EL1 in the first direction D1 may be the largest, and a distance between the first gate electrode EL1 and the substrate SUB in the third direction D3 may be the smallest. Due to the stepwise structure, each of the stack structures ST may have a thickness that decreases away from an outermost one of vertical channel structures VS to be described later, and sidewalls of the gate electrodes EL1, EL2, and EL3 may be apart from each other at a certain interval in the first direction D1 when viewed in a planar aspect.

The interlayer insulating layers ILD may have different thicknesses. For example, the lowermost one and the upper one of the interlayer insulating layers ILD may have a thickness less than that of other interlayer insulating layers ILD. However, this is not limited thereto, and the thickness of each of the interlayer insulating layers ILD may be set to have different thicknesses or the same thickness depending on the characteristics of a semiconductor device.

The interlayer insulating layers ILD may be formed of an insulating material for insulation between the gate electrodes EL1, EL2, and EL3. In particular, each of the interlayer insulating layers ILD may be formed of a metal oxide having insulating characteristics of equalizing profiles of channel holes CH formed to vertically pass through the gate electrodes EL1, EL2, and EL3 and the interlayer insulating layers ILD. In more detail, each of the interlayer insulating layers ILD may be formed of the same oxide as the gate electrodes EL1, EL2, and EL3 to equalize the profiles of the channel holes CH formed to pass vertically through the gate electrodes EL1, EL2, and EL3 and the interlayer insulating layers ILD.

For example, each of the interlayer insulating layers ILD may be formed of an oxide of a metal material constituting each of the gate electrodes EL1, EL2, and EL3. For example, as described above, when the gate electrodes EL1, EL2, and EL3 are formed of at least one metal material selected from tungsten (W), copper (Cu), aluminum (Al), titanium (Ti), tantalum (Ta), molybdenum (Mo), ruthenium (Ru), or gold (Au), each of the interlayer insulating layers ILD may be formed of an oxide of at least one metal material selected from W, Cu, Al, Ti, Ta, Mo, Ru, or Au (e.g., when each of the gate electrodes EL1, EL2, and EL3 is formed of Mo, each of the interlayer insulating layers ILD is formed of molybdenum oxide (MoOx), which is an oxide of Mo).

A plurality of channel holes CH formed to pass through portions of the stack structures ST and the substrate SUB may be provided. Vertical channel structures VS may be provided in the channel holes CH. The vertical channel structures VS may include the plurality of cell strings CSTR shown in FIG. 1 and may extend in the third direction D3 while being connected to the substrate SUB. The vertical channel structures VS may be connected to the substrate SUB by making a lower surface of a portion of each of the vertical channel structures VS be in contact with an upper surface of the substrate SUB, but the present disclosure is not limited thereto, and the vertical channel structures VS may be connected to the substrate SUB by burying the vertical channel structures VS in the substrate SUB. When a portion of each of the vertical channel structures VS is buried in the substrate SUB, the lower surface of the vertical channel structures VS may be located at a lower level than the upper surface of the substrate SUB.

A plurality of columns of the vertical channel structures VS formed to pass through any one of the stack structures ST may be provided. For example, as shown in FIG. 2, columns of the two vertical channel structures VS may be formed to pass through one of the stack structures ST. However, the present disclosure is not limited thereto, and columns of the three or more vertical channel structures VS may be formed to pass through one of the stack structures ST. In a pair of adjacent columns, the vertical channel structures VS corresponding to one column may be shifted in the first direction D1 from the vertical channel structures VS corresponding to another column adjacent thereto. In a planar aspect, the vertical channel structures VS may be arranged in a zigzag form in the first direction D1. However, the present disclosure is not limited thereto, and the vertical channel structures VS may be arranged in parallel in a row and a column.

Each of the vertical channel structures VS may extend from the substrate SUB in the third direction D3. In the drawings, each of the vertical channel structures VS is shaped like a column having upper and lower ends with the same width, but the present disclosure is not limited thereto, and each of the vertical channel structures VS may have a shape having widths in the first direction D1 and the second direction D2, which increase in the third direction D3. An upper surface of each of the vertical channel structures VS may have a circular shape, an elliptical shape, a rectangular shape, or a bar shape.

Each of the vertical channel structures VS may include a data storage pattern DSP, a vertical channel pattern VCP, a vertical semiconductor pattern VSP, and a conductive pad PAD. In each of the vertical channel structures VS, the data storage pattern DSP may have a pipe or macaroni shape of which a lower end is opened, and the vertical channel pattern VCP may have a pipe or macaroni shape of which a lower end is closed. The vertical semiconductor pattern VSP may fill a space surrounded by the vertical channel pattern VCP and the conductive pad PAD.

The data storage pattern DSP may have an inner side in contact with the vertical channel pattern VCP and an outer side in contact with sidewalls of the gate electrodes EL1, EL2, and EL3 while covering an inner wall of each of the channel holes CH. Accordingly, regions corresponding to the second gate electrodes EL2 of the data storage pattern DSP may constitute memory cells that perform a memory operation (program operation, read operation, and erase operation) by a voltage applied through the second gate electrodes EL2 together with regions corresponding to the second gate electrodes EL2 of the vertical channel pattern VCP. The memory cells correspond to the memory cell transistors MCT shown in FIG. 1. To this end, the data storage pattern DSP may be formed of a ferroelectric material to show a polarization state of electric charges due to the voltage applied through the second gate electrodes EL2 in a binary data value or a multi-leveled data value. For example, the ferroelectric-based data storage pattern DSP may represent a binary data value or a multi-leveled data value as a polarization state of electric charges. Hereinafter, the ferroelectric material may include at least one material selected from HfOₓ having an orthorhombic crystal structure, HfOₓ doped with at least one material of Al, Zr, or Si, Pb(Zr, Ti)O₃ (PZT), PbTiO₃ (PTO), SrBi₂Ti₂O₃ (SBT), Bi(La, Ti)O₃ (BLT), Pb(La, Zr)TiO₃ (PLZT), Bi(Sr, Ti)O₃ (BST), barium titanate (BaTiO₃), P(VDF-TrFE), PVDF, AlOₓ, ZnOₓ, TiOₓ, TaOₓ, or InOₓ.

The vertical channel pattern VCP may cover an inner wall of the data storage pattern DSP. The vertical channel pattern VCP may include a first portion VCP1 and a second portion VCP2 on the first portion VCP1.

The first portion VCP1 of the vertical channel pattern VCP may be provided below each of the channel holes CH and may be in contact with the substrate SUB. The first portion VCP1 of the vertical channel pattern VCP may be used to block, suppress, or minimize a leakage current in each of the vertical channel structures VS, and/or may be used as an epitaxial pattern. A thickness of the first portion VCP1 of the vertical channel pattern VCP may be, for example, larger than a thickness of the first gate electrode EL1. A sidewall of the first portion VCP1 of the vertical channel pattern VCP may be surrounded by the data storage pattern DSP. The upper surface of the first portion VCP1 of the vertical channel pattern VCP may be located at a higher level than the upper surface of the first gate electrode EL1. In more detail, the upper surface of the first portion VCP1 of the vertical channel pattern VCP may be located between the upper surface of the first gate electrode EL1 and the lower surface of the lowermost electrode of the second gate electrodes EL2. The lower surface of the first portion VCP1 of the vertical channel pattern VCP may be located at a lower level than the uppermost surface of the substrate SUB (that is, the lower surface of the lowermost layer of the interlayer insulating layers ILD). A portion of the first portion VCP1 of the vertical channel pattern VCP may overlap the first gate electrode EL1 in horizontal direction. Hereinafter, the horizontal direction refers to an arbitrary direction extending on a plane parallel to the first direction D1 and the second direction D2.

The second portion VCP2 of the vertical channel pattern VCP may extend from the upper surface of the first portion VCP1 in the third direction D3. The second portion VCP2 of the vertical channel pattern VCP may be provided between the data storage pattern DSP and the vertical semiconductor pattern VSP, and may correspond to the second gate electrodes EL2. Thus, as described above, the second portion VCP2 of the vertical channel pattern VCP may constitute memory cells together with regions corresponding to the second gate electrodes EL2 of the data storage pattern DSP.

The upper surface of the second portion VCP2 of the vertical channel pattern VCP may be substantially coplanar with the upper surface of the vertical semiconductor pattern VSP. The upper surface of the second portion VCP2 of the vertical channel pattern VCP may be located at a higher level than the upper surface of the uppermost electrode of the second gate electrodes EL2. In more detail, the upper surface of the second portion VCP2 of the vertical channel pattern VCP may be located between the upper surface and the lower surface of the third gate electrode EL3.

The vertical channel pattern VCP is a component that transfers electric charges or holes to the data storage pattern DSP, and may be formed of single crystalline silicon or polysilicon to form or boost a channel by an applied voltage. However, the present disclosure is not limited thereto, and the vertical channel pattern VCP may be formed of an oxide semiconductor material for blocking, suppressing or minimizing a leakage current. For example, the vertical channel pattern VCP may be formed of an oxide semiconductor material or a group 4 semiconductor material including at least one of indium (In), zinc (Zn), or gallium (Ga) having excellent leakage current characteristics. The vertical channel pattern VCP may be formed of a ZnOx-based material including, for example, AZO, ZTO, IZO, ITO, IGZO, or Ag—ZnO. Accordingly, the vertical channel pattern VCP may block, suppress or minimize a leakage current to the gate electrodes EL1, EL2, and EL3 or the substrate SUB and may improve the characteristics (e.g. threshold voltage distribution and speed of program/read operation) of at least one of the gate electrodes EL1, EL2, and EL3, thereby improving the electrical characteristics of the three-dimensional flash memory.

The vertical semiconductor pattern VSP may be surrounded by the second portion VCP2 of the vertical channel pattern VCP. An upper surface of the vertical semiconductor pattern VSP may be in contact with the conductive pad PAD, and a lower surface of the vertical semiconductor pattern VSP may be in contact with the first portion VCP1 of the vertical channel pattern VCP. The vertical semiconductor pattern VSP may be apart from the substrate SUB in the third direction D3. In other words, the vertical semiconductor pattern VSP may electrically float from the substrate SUB.

The vertical semiconductor pattern VSP may be formed of a material that assists diffusion of electric charges or holes in the vertical channel pattern VCP. In more detail, the vertical semiconductor pattern VSP may be formed of a material having excellent electric charge and hole mobility. For example, the vertical semiconductor pattern VSP may be formed of a semiconductor material doped with impurities, an intrinsic semiconductor material that is not doped with impurities, or a polycrystalline semiconductor material. For example, the vertical semiconductor pattern VSP may be formed of polysilicon doped with the same first conductive-type impurity (e.g., P-type impurity) as the substrate SUB. That is, the vertical semiconductor pattern VSP may improve the speed of the memory operation by improving the electrical characteristics of the three-dimensional flash memory.

Referring back to FIG. 1, the vertical channel structures VS may correspond to channels of the erasable control transistor ECT, the first and second string selection transistors SST1 and SST2, the ground selection transistor GST, and the memory cell transistors MCT.

The conductive pad PAD may be provided on the upper surface of the second portion VCP2 of the vertical channel pattern VCP and the upper surface of the vertical semiconductor pattern VSP. The conductive pad PAD may be connected to an upper portion of the vertical channel pattern VCP and an upper portion of the vertical semiconductor pattern VSP. A sidewall of the conductive pad PAD may be surrounded by the data storage pattern DSP. The upper surface of the conductive pad PAD may be substantially coplanar with the upper surface of each of the stack structures ST (i.e. upper surface of the uppermost layer of the interlayer insulating layers ILD). The lower surface of the conductive pad PAD may be located at a lower level than the upper surface of the third gate electrode EL3. In more detail, the lower surface of the conductive pad PAD may be located between the upper surface and the lower surface of the third gate electrode EL3. That is, at least a portion of the conductive pad PAD may overlap the third gate electrode EL3 in a horizontal direction.

The conductive pad PAD may be formed of a semiconductor or conductive material doped with impurities. For example, the conductive pad PAD may be formed of a semiconductor material doped with a different impurity from the vertical semiconductor pattern VSP (more precisely, a second conductive type impurity (e.g., N-type) different from the first conductive type impurity (e.g., P-type)).

The conductive pad PAD may reduce contact resistance between a bit line BL to be described later and the vertical channel pattern VCP (or the vertical semiconductor pattern VSP).

Above, although the vertical channel structures VS is described as including the conductive pad PAD, the present disclosure is not limited thereto, and the conductive pad PAD may be omitted from the vertical channel structures VS. In this case, as the conductive pad PAD is omitted from the vertical channel structures VS, the vertical channel pattern VCP and the vertical semiconductor pattern VSP may each extend in the third direction D3 to allow the upper surface of each of the vertical channel pattern VCP and the vertical semiconductor pattern VSP to be substantially coplanar with the upper surface of each of the stack structures ST (i.e., the upper surface of the uppermost layer of the interlayer insulating layers ILD). In this case, instead of being indirectly and electrically connected to the vertical channel pattern VCP through the conductive pad PAD, a bit line contact plug BLPG to be described later may be directly and electrically connected to the vertical channel pattern VCP.

Above, although the vertical channel structures VS is described as including the vertical semiconductor pattern VSP, the present disclosure is not limited thereto, and the vertical semiconductor pattern VSP may be omitted.

Above, although the vertical channel pattern VCP is described as including the first portion VCP1 and the second portion VCP2, the present disclosure is not limited thereto, and the first portion VCP1 may be excluded. For example, the vertical channel pattern VCP may be provided between the vertical semiconductor pattern VSP and the data storage pattern DSP, which extend to the substrate SUB, and may extend to the substrate SUB to be in contact with the substrate SUB. In this case, the lower surface of the vertical channel pattern VCP may be located at a lower level than the uppermost surface of the substrate SUB (the lower surface of the lowermost layer of the interlayer insulating layers ILD), and the upper surface of the vertical channel pattern VCP may be substantially coplanar with the upper surface of the vertical semiconductor pattern VSP.

A separation trench TR extending in the first direction D1 may be provided between the stack structures ST adjacent to each other. A common source region CSR may be provided in the substrate SUB exposed by the separation trench TR. The common source region CSR may extend in the first direction D1 in the substrate SUB. The common source region CSR may be formed of a semiconductor material doped with a second conductive type impurity (e.g. N-type impurity). The common source region CSR may correspond to the common source line CSL of FIG. 1.

A common source plug CSP may be provided in the separation trench TR. The common source plug CSP may be connected to the common source region CSR. The upper surface of the common source plug CSP may be substantially coplanar with the upper surface of each of the stack structures ST (i.e. upper surface of the uppermost layer of the interlayer insulating layers ILD). The common source plug CSP may have a plate shape extending in the first direction D1 and the third direction D3. In this case, the common source plug CSP may have a shape having a width in the second direction D2, which increases in the third direction D3.

Insulating spacers SP may be located between the common source plug CSP and the stack structures ST. The insulating spacers SP may be provided to face each other between the adjacent stack structures ST. For example, the insulating spacers SP may be formed of silicon oxide, silicon nitride, silicon oxynitride, or a low-k material having a low dielectric constant.

A capping insulating layer CAP may be provided on the stack structures ST, the vertical channel structures VS, and the common source plug CSP. The capping insulating layer CAP may cover the upper surface of the uppermost layer of the interlayer insulating layers ILD, the upper surface of the conductive pad PAD, and the upper surface of the common source plug CSP. The capping insulating layer CAP may be formed of an insulating material different from that of the interlayer insulating layers ILD. The bit line contact plug BLPG electrically connected to the conductive pad PAD may be provided in the capping insulating layer CAP. The bit line contact plug BLPG may have a shape having widths in the first direction D1 and the second direction D2, which increases in the third direction D3.

A bit line BL may be provided on the capping insulating layer CAP and the bit line contact plug BLPG. The bit line BL may correspond to any one of the plurality of bit lines BL0, BL1, and BL2 shown in FIG. 1, and may be formed of a conductive material and may extend in the second direction D2. A conductive material constituting the bit line BL may be the same as the conductive material forming each of the gate electrodes EL1, EL2, and EL3.

The bit line BL may be electrically connected to the vertical channel structures VS through the bit line contact plug BLPG. Here, connection of the bit line BL to the vertical channel structures VS may mean that the bit line BL is connected to the vertical channel pattern VCP included in the vertical channel structures VS.

The three-dimensional flash memory having the above-described structure may perform a program operation, a read operation, and an erase operation based on a voltage applied to each of the cell strings CSTR, a voltage applied to a string selection line SSL, a voltage applied to each of word lines WL0 to WLn, a voltage applied to the ground selection line GSL, and a voltage applied to the common source line CSL. For example, the three-dimensional flash memory may perform a program operation by forming a channel in the vertical channel pattern VCP and transferring electric charges or holes to the data storage pattern DSP of a target memory cell based on a voltage applied to each of the cell strings CSTR, a voltage applied to the string selection line SSL, a voltage applied to each of the word lines WL0 to WLn, a voltage applied to the ground selection line GSL, and a voltage applied to the common source line CSL.

The three-dimensional flash memory according to an embodiment is not limited to the described structure, and may be implemented in various structures assuming that the three-dimensional flash memory includes the vertical channel pattern VCP, the data storage pattern DSP, the gate electrodes EL1, EL2, and EL3, the bit line BL, and the common source line CSL, according to an implementation example.

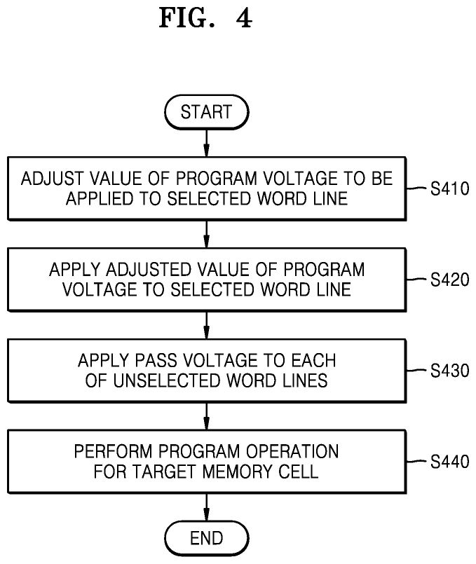

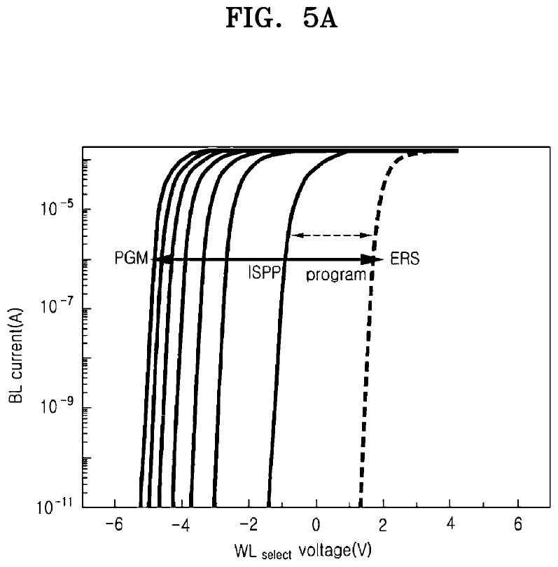

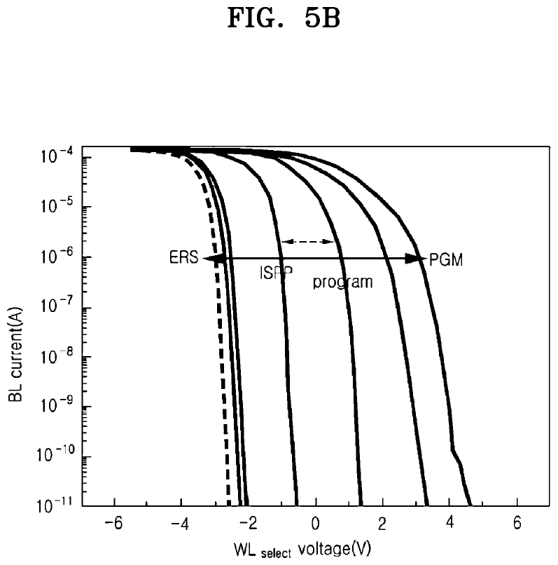

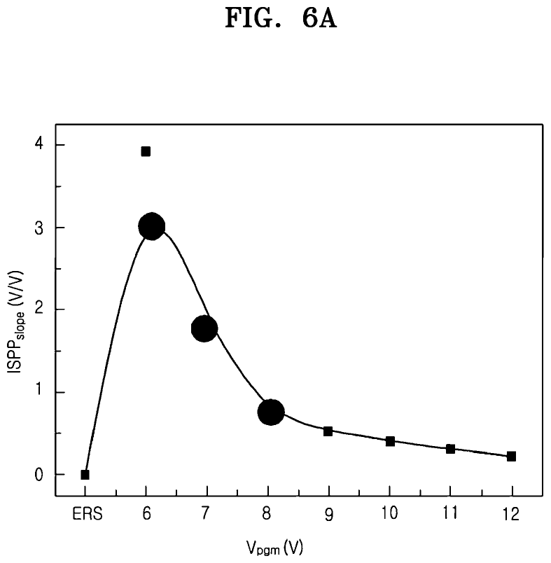

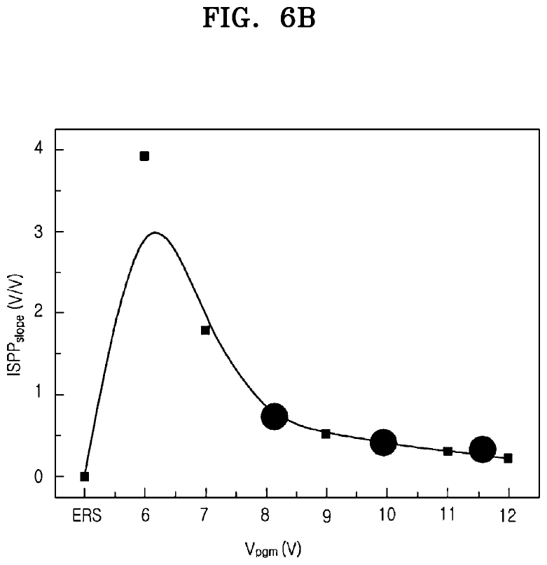

FIG. 4 is a flowchart illustrating a program operation method of a three-dimensional flash memory according to an embodiment, and FIGS. 5A to 6B are diagrams for describing adjusting a value of a program voltage in the program operation method illustrated in FIG. 4. In more detail, FIG. 5A is a diagram for describing adjusting a value of a program voltage when a vertical channel pattern is of an N type, FIG. 5B is a diagram for describing adjusting a value of a program voltage when a vertical channel pattern is a P type, and FIGS. 6A and 6B are diagrams for describing adjusting a value of a program voltage based on a slope in which a voltage pulse increases in an ISPP method when a vertical channel pattern is of an N type.

Hereinafter, the program operation method described above is assumed to be performed by the three-dimensional flash memory having the structure described above with reference to FIGS. 1 to 3.

Referring to FIG. 4, in operation S410, the three-dimensional flash memory may adjust a value of a program voltage V_{PGM} to be applied to a selected word line Sel WL corresponding to a target memory cell (Sel memory cell), which is a target of a program operation from among the word lines WL0 to WLn, by applying an incremental step pulse programming (ISPP) method.

In operation S420, the three-dimensional flash memory may apply the program voltage V_{PGM} of the adjusted value to the selected word line Sel WL.

In operation S430, the three-dimensional flash memory may apply a pass voltage V_{PASS} to each of unselected word lines Unsel WLs other than the selected word line Sel WL from among the word lines WL0 to Win.

In operation S440, the three-dimensional flash memory may perform a program operation on a target memory cell (Sel memory cell) in response to a program voltage V_{PGM} being applied to the selected word line Sel WL and the pass voltage V_{PASS} being applied to each of the unselected word lines Unsel WLs.

In this case, the three-dimensional flash memory may have different voltages applied during the program operation according to a type of the vertical channel pattern VCP.

For example, when the vertical channel pattern VCP is of an N type, the three-dimensional flash memory may adjust the program voltage V_{PGM} to a positive (+) value in operation S410 in consideration of a value of a threshold voltage as illustrated in FIG. 5A. The program voltage +V_{PGM} of a positive value may have a value between 5 V and 12 V. For example, the program voltage +V_{PGM} of a positive value may have a value of 5 V. Thus, in operation S420, the three-dimensional flash memory may apply the program voltage +V_{PGM} adjusted to a positive value, to the selected word line Sel WL. In operation S430, the three-dimensional flash memory may adjust the pass voltage V_{PASS} to be applied to each of unselected word lines Unsel WLs based on the stability of a program state that the target memory cell (Sel memory cell) has due to the program operation and may then apply the adjusted pass voltage V_{PASS} to each of the unselected word lines Unsel WLs. Similarly, the three-dimensional flash memory may adjust the pass voltage V_{PASS} to a positive (+) value. The pass voltage +V_{PASS} of a positive value may have a value less than or equal to 6 V, which satisfies a condition less than the program voltage +V_{PGM} of a positive value and a condition less than a threshold value at which an amount of change in a threshold voltage abruptly increases. For example, the pass voltage +V_{PASS} of a positive value may have a value of 2 V.

In this case, in operation S430, the three-dimensional flash memory may apply a ground voltage (0V) to a bit line Sel BL connected to a selected vertical channel structure Sel VS including the target memory cell (Sel memory cell) of the vertical channel structures VS and apply a voltage (a positive power voltage (Vcc), e.g., +2 V) for self-boosting the vertical channel pattern VCP of an unselected vertical channel structure Unsel VS to a bit line Unsel BL connected to the unselected vertical channel structure Unsel VS (vertical channel structure that does not include the target memory cell (Sel memory cell)) other than the selected vertical channel structure Sel VS of the vertical channel structures VS.

Accordingly, a program operation for the target memory cell (Sel memory cell) may be performed in the vertical channel structures VS in which the vertical channel pattern VCP is of an N type.

As such, when the vertical channel pattern VCP is of an N type, the three-dimensional flash memory may adjust a value of the program voltage V_{PGM} to be applied to the selected word line Sel WL based on a slope in which a voltage pulse increases in an ISPP method. In more detail, the three-dimensional flash memory may adjust a value of the program voltage V_{PGM} based on an amount of change by which a voltage pulse increases or a threshold voltage window in the slope. For example, the three-dimensional flash memory may determine and adjust a value of the program voltage V_{PGM} in a region having a large threshold voltage window in an ISPP slope as illustrated in FIG. 6A. As another example, the three-dimensional flash memory may determine and adjust a value of the program voltage V_{PGM} in a region in which an amount of change, by which a voltage pulse increase, is gradual in the ISPP slope as illustrated in FIG. 6B.

In a process of adjusting a value of the program voltage V_{PGM} based on a slope in which a voltage pulse increases in the ISPP method, a value of the program voltage V_{PGM} may be adjusted to a plurality of values to multi-level the three-dimensional flash memory. For example, as shown in FIG. 6A, a value of the program voltage V_{PGM} may be determined and adjusted to values of 6 V, 6.75 V, and 8 V and may then be applied to the selected word line Sel WL, and thus program states corresponding to values of 6 V, 6.75 V, and 8 V may be programmed.

As another example, when the vertical channel pattern VCP is of a P-type, the three-dimensional flash memory may adjust the program voltage V_{PGM} to a negative (−) value in operation S410 in consideration of a value of a threshold voltage as illustrated in FIG. 5B. The program voltage −V_{PGM} of a negative value may have a value between −12 V and −5 V. For example, the program voltage −V_{PGM} of a negative value may have a value of −5 V. Thus, in operation S420, the three-dimensional flash memory may apply the program voltage −V_{PGM} adjusted to a negative value, to the selected word line Sel WL. In operation S430, the three-dimensional flash memory may adjust the pass voltage V_{PASS} to be applied to each of the unselected word lines Unsel WLs based on the stability of a program state that the target memory cell (Sel memory cell) has due to the program operation and may then apply the adjusted pass voltage V_{PASS} to each of the unselected word lines Unsel WLs. Similarly, the three-dimensional flash memory may adjust the pass voltage V_{PASS} to a negative (−) value. The pass voltage −V_{PASS} of a negative value may have a value that satisfies a condition greater than the program voltage −V_{PGM} of a negative value and a condition less than a threshold value at which an amount of a change in a threshold voltage abruptly increases. For example, the pass voltage −V_{PASS} of a negative value may have a value of −2 V.

In this case, in operation S430, the three-dimensional flash memory may apply a ground voltage (0V) to a bit line Sel BL connected to a selected vertical channel structure Sel VS including the target memory cell (Sel memory cell) of the vertical channel structures VS and apply a voltage (a negative power voltage (Vcc), e.g., −2 V) for self-boosting the vertical channel pattern VCP of an unselected vertical channel structure Unsel VS to a bit line Unsel BL connected to the unselected vertical channel structure Unsel VS (vertical channel structure that does not include the target memory cell (Sel memory cell)) other than the selected vertical channel structure Sel VS of the vertical channel structures VS.

Accordingly, a program operation for the target memory cell (Sel memory cell) may be performed in the vertical channel structures VS in which the vertical channel pattern VCP is of a P type.

Although not described in a separate drawing, in a process in which the vertical channel pattern VCP adjusts a value of the program voltage V_{PGM} in the vertical channel structures VS of a P type, the value of the program voltage V_{PGM} may be adjusted to a plurality of values to multi-level the three-dimensional flash memory. In the vertical channel structures VS in which the vertical channel pattern VCP is of a P type, the value of the program voltage V_{PGM} is adjusted to a plurality of values, which is the same as in the case in which the value of the program voltage V_{PGM} is adjusted to a plurality of values in the vertical channel structures VS in which the vertical channel pattern VCP is of an N type except that a sign of the value of the program voltage V_{PGM} is opposite, and thus a detailed description thereof will be omitted.

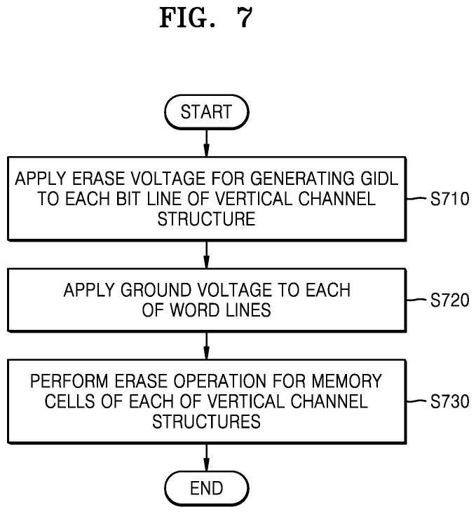

FIG. 7 is a flowchart illustrating an erase operation method of a three-dimensional flash memory, according to an embodiment.

Hereinafter, the erase operation method described above is assumed to be performed by the three-dimensional flash memory having the structure described above with reference to FIGS. 1 to 3.

Referring to FIG. 7, in operation S710, the three-dimensional flash memory may apply an erase voltage V_{ERASE} for generating a gate induced drain leakage (GIDL) with a string selection line (SSL), to a bit line of each of vertical channel structures included in a block of the vertical channel structures VS, which a target of an erase operation.

In operation S720, the three-dimensional flash memory may apply a ground voltage (0V) to each of the word lines WL0 to WLn.

In operation S730, in response to GIDL being generated in each of the vertical channel structures VS included in the block, the three-dimensional flash memory may perform an erase operation on memory cells of each of the vertical channel structures VS included in the block.

An erase operation for each type of the vertical channel pattern VCP based on the aforementioned operations S710 to S730 is now described in detail, and when the vertical channel pattern VCP is of an N type, in operation S710, the three-dimensional flash memory may apply the erase voltage +V_{ERASE} of a positive value, to a bit line of each of vertical channel structures included in a block as a target of an erase operation. The erase voltage +V_{ERASE} of a positive value may have a value between 5 V and 12 V. For example, the erase voltage +V_{ERASE} of a positive value may have a value of 10 V. Accordingly, an erase operation may be performed on the vertical channel structures VS having the vertical channel pattern VCP of an N type.

On the other hand, when the vertical channel pattern VCP is of a P type, in operation S710, the three-dimensional flash memory may apply an erase voltage −V_{ERASE} of a negative value to a bit line of each of vertical channel structures included in the block as the target of the erase operation. The erase voltage −V_{ERASE} of a negative value may have a value between −12 V and −5 V. For example, the erase voltage −V_{ERASE} of a negative value may have a value of −10 V. Accordingly, an erase operation may be performed on the vertical channel structures VS having the vertical channel pattern VCP of a P type.

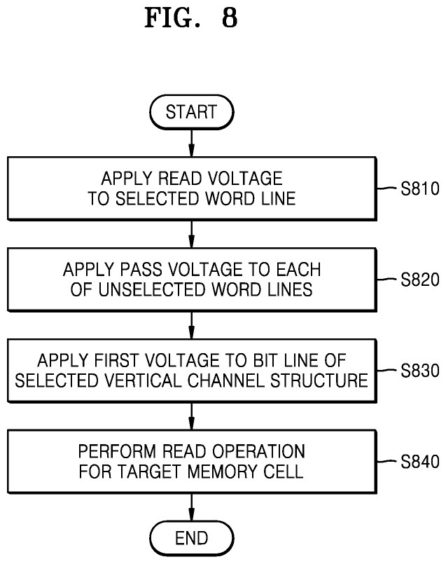

FIG. 8 is a flowchart illustrating a read operation method of a three-dimensional flash memory, according to an embodiment.

Hereinafter, the read operation method described above is assumed to be performed by the three-dimensional flash memory having the structure described above with reference to FIGS. 1 to 3.

Referring to FIG. 8, in operation S810, the three-dimensional flash memory may apply a read voltage V_{READ} to a selected word line Sel WL corresponding to the target memory cell (Sel memory cell) that is a target of the read operation from among the word lines WL0 to Win.

In this case, the read voltage V_{READ} may be adjusted to minimize an effect of the target memory cell (Sel memory cell) on the pass voltage V_{PASS} described later. For example, when the vertical channel pattern VCP is of an N type, the read voltage V_{READ} may be adjusted to a value of 4 V to 6 V. For example, when the vertical channel pattern VCP is of a P type, the read voltage V_{READ} may be adjusted to a value of −6 V to −4 V.

In operation S820, the three-dimensional flash memory may apply a pass voltage V_{PASS} to each of unselected word lines Unsel WLs other than the selected word line Sel WL from among the word lines WL0 to WLn.

In operation S830, the three-dimensional flash memory may apply a first voltage V₁ to the bit line Sel BL of the selected vertical channel structure Sel VS included in the target memory cell (Sel memory cell) from among the vertical channel structures VS.

In operation S840, the three-dimensional flash memory may perform the read operation, on the target memory cell (Sel memory cell) in response to the read voltage V_{READ} of being applied to the selected word line Sel WL, the pass voltage V_{PASS} being applied to each of the unselected word lines Unsel WLs, and the first voltage V₁ being applied to the bit line Sel BL of the selected vertical channel structure Sel VS.

A read operation for each type of the vertical channel pattern VCP based on the aforementioned operations S810 to S840 is now described in detail, and when the vertical channel pattern VCP is of an N type, in operation S810, the three-dimensional flash memory may apply the read voltage +V_{READ} of a positive value, to the selected word line Sel WL. In operation S820, the three-dimensional flash memory may apply the pass voltage +V_{PASS} (e.g., +2 V) of a positive value to each of the unselected word lines Unsel WLs. In operation S830, the three-dimensional flash memory may apply a first voltage V₁ (e.g., +1 V) of a positive value to the bit line Sel BL of the selected vertical channel structure Sel VS including the target memory cell (Sel memory cell) from among the vertical channel structures VS and apply the ground voltage (0V) to the bit line Unsel VS of the unselected vertical channel structure Unsel VS that does not include the target memory cell (Sel memory cell) from among the vertical channel structures VS.

Accordingly, a read operation for the target memory cell (Sel memory cell) may be performed in the vertical channel structures VS in which the vertical channel pattern VCP is of an N type.

On the other hand, when the vertical channel pattern VCP is of a P type, in operation S810, the three-dimensional flash memory may apply the read voltage −V_{READ} of a negative value to the selected word line Sel WL. In operation S820, the three-dimensional flash memory may apply the pass voltage (−V_{PASS} (e.g., −2 V) of a negative value to each of the unselected word lines Unsel WLs. In operation S830, the three-dimensional flash memory may apply a first voltage V₁ (e.g., −1 V) of a negative value to the bit line Sel BL of the selected vertical channel structure Sel VS including the target memory cell (Sel memory cell) from among the vertical channel structures VS and apply the ground voltage (0V) to the bit line Unsel VS of the unselected vertical channel structure Unsel VS that does not include the target memory cell (Sel memory cell) from among the vertical channel structures VS.

Accordingly, a read operation for the target memory cell (Sel memory cell) may be performed in the vertical channel structures VS in which the vertical channel pattern VCP is of a P type.

Although the embodiments described above have been described with reference to the limited embodiments and drawings, various modifications and variations may be made by those skilled in the art. For example, appropriate results may be achieved even if the described technologies are performed in a different order than the described method, and/or components of the described system, structure, device, circuit, etc. are coupled or combined in a different form than the described method, or other components or equivalent components are replaced or substituted.

Therefore, other implementations, other embodiments, and equivalents of the claims fall within the scope of the following claims.

1. A program operation method of a three-dimensional flash memory including word lines apart from each other and stacked in a vertical direction while extending in a horizontal direction on a substrate, and vertical channel structures formed to pass through the word lines and extending in the vertical direction, each of the vertical channel structures including a vertical channel pattern extending in the vertical direction and a ferroelectric-based data storage pattern formed to cover an outer wall of the vertical channel pattern, and the data storage pattern and the vertical channel pattern constituting memory cells corresponding to the word lines, the method comprising:
adjusting a value of a program voltage to be applied to a selected word line corresponding to a target memory cell as a target of the program operation from among the word lines by applying an incremental step pulse programming (ISPP) method;
applying the adjusted value of the program voltage to the selected word line;
applying a pass voltage to each of unselected word lines except for the selected word line from among the word lines; and
performing the program operation on the target memory cell in response to the adjusted value of the program voltage being applied to the selected word line and the pass voltage being applied to the unselected word lines.

2. The method of claim 1, wherein the adjusting of the value of the program voltage includes adjusting the value of the program voltage to be applied to the selected word line corresponding to the target memory cell as the target of the program operation from among the word lines, based on a slope in which a voltage pulse increases in the ISPP method.

3. The method of claim 2, wherein the adjusting of the value of the program voltage includes multi-leveling the three-dimensional flash memory by adjusting the voltage of the program voltage to a plurality of values.

4. The method of claim 1, wherein, when a vertical channel pattern of a selected vertical channel structure including the target memory cell is of an N type, the adjusting of the value of the program voltage includes adjusting the value of the program voltage to a positive value, and
the applying of the pass voltage includes applying a pass voltage of a positive value.

5. The method of claim 1, wherein, when a vertical channel pattern of a selected vertical channel structure including the target memory cell is of a P type, the adjusting of the value of the program voltage includes adjusting the value of the program voltage to a negative value, and
the applying of the pass voltage includes applying a pass voltage of a negative value.

6. The method of claim 1, wherein the applying of the pass voltage includes adjusting a value of the pass voltage based on stability of a program state that the target memory cell has due to the program operation.
